(19) United States
(12) Patent Application Publication
(10) Pub. No.: US 2025/0056821 A1
(43) Pub. Date: Feb. 13, 2025

(54) INSULATED GATE BIPOLAR TRANSISTOR

(71) Applicant: Mosel Vitelic Inc., Hsinchu (TW)

(72) Inventors: Ming-Chuan Chen, Hsinchu (TW); Yun-Kuei Chiu, Hsinchu (TW)

(21) Appl. No.: 18/416,830

(22) Filed: Jan. 18, 2024

(30) Foreign Application Priority Data
Aug. 7, 2023 (TW) 112129584

(51) Int. Cl. H01L 29/739; H01L 29/06; H01L 29/08; H01L 29/423

(52) U.S. Cl. CPC H01L 29/7393; H01L 29/0696; H01L 29/0804; H01L 29/0821; H01L 29/4236

(57) ABSTRACT

An insulated gate bipolar transistor is disclosed and includes a substrate, a collector, a gate, an isolation layer and a plurality of emitters. The substrate includes a trench and a drift area. The drift area is disposed corresponding to a first surface and includes a first conductive type. The trench is concaved from the first surface toward the drift area. The collector is formed on a second surface of the substrate and includes a second conductive type. The gate is formed in the trench. The isolation layer is formed between the gate and an inner wall of the trench, and includes side lines. The emitters are formed from the first surface of the substrate toward the drift area, are disposed adjacent to the side lines, and include the first conductive type. The emitters are arranged at intervals along the side lines, respectively.

### CROSS-REFERENCE TO RELATED APPLICATION

This application claims priority to Taiwan Patent Application No. 112129584, filed on Aug. 7, 2023. The entirety of the above-mentioned patent application is incorporated herein by reference for all purposes.

### FIELD OF THE INVENTION

The present disclosure relates to a semiconductor device, and more particularly to an insulated gate bipolar transistor.

### BACKGROUND OF THE INVENTION

Generally, the insulated gate bipolar transistor (IGBT) is commonly used in the AC motor of the electric vehicle for controlling the output current, and has the advantages of low driving current and low on-resistance. However, when a short circuit occurs with a larger short circuit current, the insulated gate bipolar transistor would be burned out in a short time. Conversely, if the saturation current is suppressed to reduce the short circuit current, the collector-emitter saturation voltage of the insulated gate bipolar transistor would be increased, and the energy loss would be caused. Therefore, the short circuit current needs to be controlled within an appropriate range to avoid device damage or energy loss.

FIG. 1 is a cross-sectional view illustrating an insulated gate bipolar transistor of a prior art. The insulated gate bipolar transistor 900 includes a plurality of gates 901, a hot carrier injection area 902, a plurality of emitters 903 and a plurality of well areas 904. The well areas 904 are formed on an upper surface of the hot carrier injection area 902. Each of the well areas 904 is disposed between two adjacent gates 901. The plurality of emitters 903 are formed on the two lateral sides of the plurality of gates 901, respectively. The short circuit current is in relation to the density of the emitters 903, and the density of the emitters 903 is in relation to a distance D of two adjacent gates 901. Hence, by adjusting the distance D, the short circuit current of the insulated gate bipolar transistor 900 can be adjusted to reach an appropriate range. However, in response to different wafer designs, the above-mentioned adjusting method needs a large number of different wafers and masks for developing and testing, and it is necessary to adjust the position of multiple components, such as gates, insulating layers and emitters, so as to adjust the short circuit current to an appropriate range, which results in high cost.

Therefore, there is a need of providing an insulated gate bipolar transistor to obviate the drawbacks encountered from the prior arts.

### SUMMARY OF THE INVENTION

It is an objective of the present disclosure to provide an insulated gate bipolar transistor, which achieves the advantages of reducing cost, preventing from damage, and reducing energy loss.

In accordance with an aspect of the present disclosure, an insulated gate bipolar transistor is disclosed, and includes a substrate, a collector, at least one gate, at least one isolation layer and a plurality of emitters. The substrate includes at least one trench, a drift area, a first surface and a second surface. The first surface and the second surface are two opposite surfaces of the substrate. The drift area is disposed corresponding to the first surface, and includes a first conductive type. The at least one trench is concaved from the first surface toward the drift area. The at least one trench includes an inner wall. The collector is formed on the second surface of the substrate, and includes a second conductive type which is opposite to the first conductive type. The at least one gate is formed in the at least one trench. The at least one isolation layer is formed between the at least one gate and the inner wall of the at least one trench, and includes at least one lateral side. The plurality of emitters are formed from the first surface of the substrate toward the drift area, are disposed adjacent to the at least one side of the isolation layer, and include the first conductive type. The plurality of emitters are arranged at intervals along the at least one lateral side.

### BRIEF DESCRIPTION OF THE DRAWINGS

FIG. 1 is a cross-sectional view illustrating an insulated gate bipolar transistor of a prior art;

FIG. 2 is a cross-sectional view illustrating an insulated gate bipolar transistor according to an embodiment of the present disclosure;

FIG. 3 is a partially enlarged top view of the insulated gate bipolar transistor of FIG. 2; and

FIG. 4 is a cross-sectional view illustrating an insulated gate bipolar transistor according to another embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

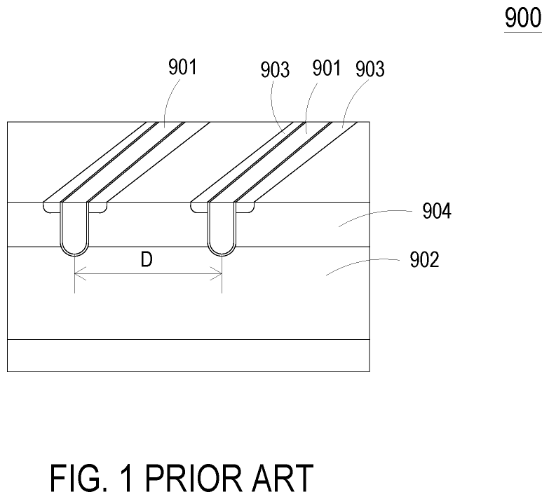

FIG. 1 is a cross-sectional view illustrating an insulated gate bipolar transistor of a prior art. In the present embodiment, the insulated gate bipolar transistor 100 includes a substrate 1, a collector 2, at least one gate 3, at least one isolation layer 4 and a plurality of emitters 5. The substrate 1 includes at least one trench 11, a drift area 12, a first surface 13 and a second surface 14. The first surface 13 and the second surface 14 are two opposite surfaces of the substrate 1. The drift area 12 is disposed corresponding to the first surface 13, and includes a first conductive type. In the present embodiment, the first conductive type is the N-type semiconductor, but not limited thereto. The at least one trench 11 is concaved from the first surface 13 toward the drift area 12. The at least one trench 11 includes an inner wall (not shown). The collector 2 is formed on the second surface 14 of the substrate 1. The collector 2 includes a second conductive type which is opposite to the first conductive type. In the present embodiment, the second conductive type is the P-type semiconductor, but not limited thereto. The at least one gate 3 is formed in the at least one trench 11. The at least one isolation layer 4 is formed between the at least one gate 3 and the inner wall of the at least one trench 11. The at least one isolation layer 4 includes at least one lateral side. In the present embodiment, the insulated gate bipolar transistor 100 for example but not limited to include a plurality of gates 3, a plurality of isolation layers 4 and a plurality of trenches 11. Each of the gates 3 is disposed in corresponding one of the trenches 11. Each of the isolation layers 4 is formed between corresponding gate 3 and inner wall of corresponding trench 11. In the present embodiment, the at least one lateral side of each isolation layer 4 includes a first side 41 and a second side 42. The first side 41 and the second side 42 are two opposite sides of the isolation layer 4, but not limited thereto. The plurality of emitters 5 are formed from the first surface 13 of the substrate 1 toward the drift area 12, and disposed adjacent to the first side 41 or the second side 42 of the isolation layer 4. The plurality of emitters 5 include the first conductive type, respectively. The plurality of emitters 5 are arranged at intervals along an extending direction of the first side 41 or the second side 42, so that the short circuit current of the insulated gate bipolar transistor 100 is adjusted to an appropriate range.

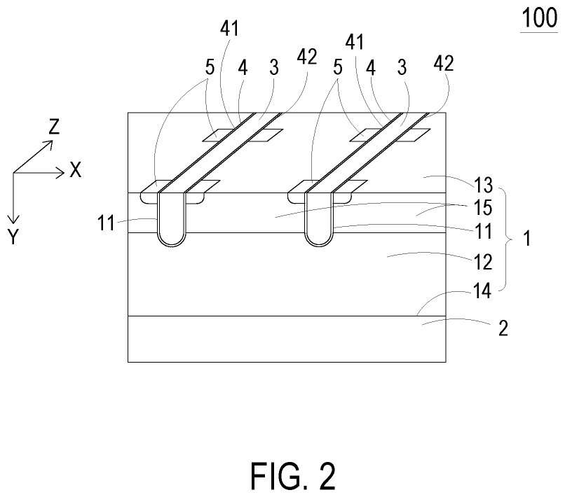

As shown in FIG. 2, the trench 11 of the present embodiment includes a width direction X, a depth direction Y and a length direction Z. The width direction X, the depth direction Y and the length direction Z for example but not limited to be perpendicular to each other. The plurality of trenches 11 are arranged at intervals along the width direction X, but not limited thereto. Each of the trenches 11 is formed from the first surface 13 toward the depth direction Y. The plurality of emitters 5 are arranged at intervals along the length direction Z, but not limited thereto. In the present embodiment, the emitters 5 disposed adjacent to the first side 41 and the emitters 5 disposed adjacent to the second side 42 are symmetrically disposed on two sides of the trench 11.

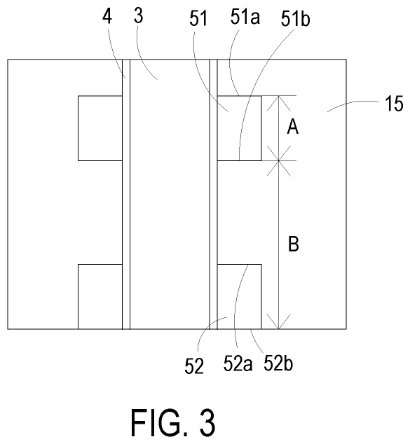

FIG. 3 is a partially enlarged top view of the insulated gate bipolar transistor of FIG. 2. In the present embodiment, the plurality of emitters 5 include a first emitter 51 and a second emitter 52. The first emitter 51 has a first end 51a and a second end 51b opposite to each other. A first distance A is formed between the first end 51a and the second end 51b. The second emitter 52 has a third end 52a and a fourth end 52b. The third end 52a of the second emitter 52 is disposed adjacent to the second end 51b of the first emitter 51. A second distance B is formed between the second end 51b of the first emitter 51 and the fourth end 52b of the second emitter 52. The short circuit current of the insulated gate bipolar transistor 100 is related to the ratio of the second distance B and the first distance A (B/A). Preferably, the above-mentioned ratio (second distance B/first distance A) of the present embodiment is in a range between 10% to 70%, but not limited thereto. By adjusting the length and distance of the first emitter 51 and the second emitter 52, the first distance A and the second distance B are correspondingly changed, so that the short circuit current of the insulated gate bipolar transistor 100 is adjusted to the appropriate range. Since the short circuit current of the insulated gate bipolar transistor 100 is simply adjusted by adjusting the position and length of the first emitter 51 and the second emitter 52, and it is unnecessary to change the positions or arrangements of other components of the insulated gate bipolar transistor 100, the advantages of low cost and easily developing are achieved.

In the present embodiment, the substrate 1 further includes a plurality of well areas 15. Each of the well areas 15 is formed on the drift area 12, and disposed between two adjacent trenches 11. The plurality of emitters 5 are formed in the plurality of well areas 15. The plurality of well areas 15 include the second conductive type, but not limited thereto.

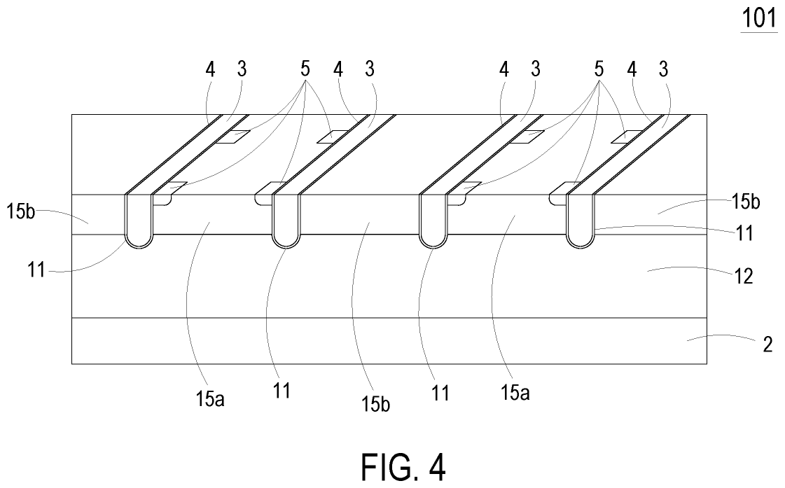

FIG. 4 is a cross-sectional view illustrating an insulated gate bipolar transistor according to another embodiment of the present disclosure. The structure of the insulated gate bipolar transistor 101 of the present embodiment is similar to the insulated gate bipolar transistor 100 of FIG. 2. The same references represent the same components and functions, and would not be redundantly described hereinafter. The plurality of well areas 15 of the substrate 1 of the insulated gate bipolar transistor 101 include at least one active area 15a and at least one dummy cell 15b, wherein the at least one active area 15a includes the second conductive type. In the present embodiment, the plurality of well areas 15 for example but not limited to include a plurality of active areas 15a and a plurality of dummy cells 15b. The plurality of active areas 15a and the plurality of dummy cells 15b are formed on the drift area 12, respectively, and disposed between two adjacent trenches 11, respectively. In the present embodiment, each of the active areas 15a is disposed between two dummy cells 15b, or each of the dummy cells 15b is disposed between two active areas 15a, but not limited thereto. The plurality of emitters 5 are formed in the plurality of active areas 15a, respectively. The dummy cells 15b are configured for adjusting the density of the pattern density or isolating the gates 3. Due to the arrangements of the dummy cells 15b, the function equivalent to adjusting the distance between the gates 3 is achieved, and the short circuit current of the insulated gate bipolar transistor 101 is adjusted to the appropriate range. In addition, since the short circuit current of the insulated gate bipolar transistor 101 is simply adjusted by adjusting the position and length of the dummy cell 15b, and it is unnecessary to change the positions or arrangements of other components of the insulated gate bipolar transistor 101, the advantages of low cost and easily developing are achieved. In some embodiments, the active areas 15a and the dummy cells 15b of the plurality of well areas 15 can be disposed between any two adjacent gates 3 according to practical requirements, which are not limited to the above-mentioned embodiments.

From the above descriptions, the present disclosure provides an insulated gate bipolar transistor including at least one trench, and at least one lateral side of each trench includes a plurality of emitters. By adjusting the length and distance of the emitters to change the first distance and the second distance, the short circuit current of the insulated gate bipolar transistor is adjusted to the appropriate range, and the advantages of low cost and easily developing are achieved. Due to the arrangements of the dummy cells, the function equivalent to adjusting the distance between the gates is achieved, the short circuit current of the insulated gate bipolar transistor is adjusted to the appropriate range, and the advantages of low cost and easily developing are achieved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An insulated gate bipolar transistor, comprising:
a substrate comprising at least one trench, a drift area, a first surface and a second surface, wherein the first surface and the second surface are two opposite surfaces of the substrate, the drift area is disposed corresponding to the first surface, and comprises a first conductive type, wherein the at least one trench is concaved from the first surface toward the drift area, wherein the at least one trench comprises an inner wall;
a collector formed on the second surface of the substrate, and comprising a second conductive type which is opposite to the first conductive type;
at least one gate formed in the at least one trench;
at least one isolation layer formed between the at least one gate and the inner wall of the at least one trench, and comprising at least one lateral side; and
a plurality of emitters formed from the first surface of the substrate toward the drift area, disposed adjacent to the at least one side of the isolation layer, and comprising the first conductive type, wherein the plurality of emitters are arranged at intervals along the at least one lateral side.

2. The insulated gate bipolar transistor according to claim 1, wherein the plurality of emitters comprise a first emitter and a second emitter, the first emitter has a first end and a second end opposite to each other, and a first distance is formed between the first end and the second end, wherein the second emitter has a third end and a fourth end, the third end of the second emitter is disposed adjacent to the second end of the first emitter, wherein a second distance is formed between the second end of the first emitter and the fourth end of the second emitter, wherein the short circuit current of the insulated gate bipolar transistor is related to the ratio of the second distance and the first distance.

3. The insulated gate bipolar transistor according to claim 1, wherein the at least one lateral side of the at least one isolation layer comprises a first side and a second side, wherein the first side and the second side are two opposite sides of the isolation layer, wherein the plurality of emitters are disposed adjacent to the first side or the second side of the isolation layer, and are arranged at intervals along the first side or the second side.

4. The insulated gate bipolar transistor according to claim 1, wherein the at least one trench comprises a plurality of trenches, and the at least one gate comprises a plurality of gates, wherein each of the gates is disposed in corresponding one of the trenches.

5. The insulated gate bipolar transistor according to claim 4, wherein the substrate comprises a plurality of well areas, each of the well areas is formed on the drift area, and disposed between two adjacent trenches, wherein the plurality of well areas comprise the second conductive type.

6. The insulated gate bipolar transistor according to claim 5, wherein the plurality of well areas comprise at least one active area and at least one dummy cell, the at least one active area and the at least one dummy cell are formed on the drift area, respectively, and disposed between two adjacent trenches, respectively, wherein the at least one active area comprises the second conductive type.

7. The insulated gate bipolar transistor according to claim 6, wherein the at least one active area comprises a plurality of active areas, and the at least one dummy cell comprises a plurality of dummy cells, wherein each of the active areas is disposed between two dummy cells, or each of the dummy cells is disposed between two active areas.

8. The insulated gate bipolar transistor according to claim 1, wherein the first conductive type is the N-type semiconductor, and the second conductive type is the P-type semiconductor.
